(19) United States
(12) Patent Application Publication
(10) Pub. No.: US 2005/0153249 A1
(43) Pub. Date: Jul. 14, 2005

(54) Electronic component manufacturing apparatus, electronic component manufacturing method, and electronic component

(75) Inventors: Naoko Yamaguchi, Yokohama-shi (JP); Hideo Aoki, Yokohama-shi (JP); Chiaki Takubo, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 10/866,341

(22) Filed: Jun. 14, 2004

(30) Foreign Application Priority Data
Jan. 13, 2004 (JP) P2004-005046

(51) Int. Cl. G03F 7/00

(52) U.S. Cl. 430/330; 430/314; 430/319

(57) ABSTRACT

There are provided a metal particulate spraying step to spray metal particulates over a substrate having an insulating pattern formed of thermosetting resin, a heating step to heat and dissolve the resin pattern and fix the metal particulates on the resin pattern, and a metal particulate eliminating step to eliminate metal particulates attached on the surface of the substrate excluding the resin pattern.

### CROSS REFERENCE TO THE INVENTION

This application is based upon and claims the benefit of priority from the prior Japanese Patent Application No. 2004-05046 filed on Jan. 13, 2004; the entire contents of which are incorporated herein by reference.

### BACKGROUND OF THE INVENTION

1. Field of the Invention

The present invention relates to an electronic component manufacturing apparatus, an electronic component manufacturing method, and an electronic component.

2. Description of the Related Art

In recent years, electrophotographic methods to form an electronic circuit pattern on a substrate are developed. In the electrophotographic method to form an electronic circuit pattern, an electrostatic latent image of a specific pattern is formed on a photoreceptor, and insulating resin particles, over the surface of each of which metal particulates adhere, are electrostatically attached on the electrostatic latent image to form a visible image, which is then transferred to the substrate, forming an electronic circuit pattern.

With the conventional method of forming an electronic circuit pattern described above, is formed a resin layer containing metal particulates, which is insulating resin in which metal particulates disperse almost evenly. Further, the metal particulates positioned on the surface of the metal-particulate-containing resin layer are used as a plating nucleus, in forming a conductive metal layer by electroless plating or electrolytic plating.

However, because of the inclusion of the metal particulates in the metal-particulate-containing resin layer formed by dissolving plural particles of the insulating resin particles attaching metal particulates over the surface thereof, the adhesiveness of the interface between the contained metal particulates and the resin affects the material to easily crack which is a cause of a damage. As a result, the strength of the resin layer in its entirety becomes insufficient.

In order to solve the above problem, attained is the present invention, aiming at providing apparatuses and methods to manufacture an electronic component capable of forming a wiring pattern of superior adhesiveness with a substrate, and providing an electronic component having such an wiring pattern.

### SUMMARY OF THE INVENTION

According to an aspect of the present invention, there is provided an electronic component manufacturing apparatus, comprising: a metal particulate spraying mechanism to spray metal particulates over a substrate having an insulating pattern formed of thermosetting resin and attach the metal particulates on said insulating pattern; a heating mechanism to heat and dissolve said insulating pattern and fix said metal particulates on said insulating pattern; and a metal particulate eliminating mechanism to eliminate the metal particulates attached on the surface of the substrate excluding said insulating pattern.

Further, according to an aspect of the present invention, is provided an electronic component manufacturing apparatus, comprising: a liquid attaching mechanism to attach liquid, containing a specific ratio of metal particulates and vaporizing at a specific temperature, on a substrate having an insulating pattern formed of thermosetting resin; a heating mechanism to heat said insulating pattern to which said liquid is attached, vaporize said liquid and at the same time dissolve said insulating pattern, and fix said metal particulates on said insulating pattern; and a metal particulate eliminating mechanism to eliminate the metal particulates attached on the substrate excluding said insulating pattern.

Furthermore, according to an aspect of the present invention, there is provided a method of manufacturing an electronic component, comprising: a metal particulate spraying step to spray metal particulates over a substrate having an insulating pattern formed of thermosetting resin and attach the metal particulates on said insulating pattern; a heating step to heat and dissolve said insulating pattern and fix said metal particulates on said insulating pattern; and a metal particulate eliminating step to eliminate the metal particulates attached on the surface of the substrate excluding said insulating pattern.

Further, according to an aspect of the present invention, there is provided a method of manufacturing an electronic component, comprising: a dissolving step to heat and dissolve an insulating pattern formed of thermosetting resin and formed on a substrate; a metal particulate spraying step to spray metal particulates over said substrate having the insulating pattern which is dissolved, and attach the metal particulates on the dissolved insulating pattern; a curing step to heat and cure said insulating pattern, which has said metal particulates attached thereon, and fix said metal particulates on said insulating pattern; and a metal particulate eliminating step to eliminate the metal particulates attached on the surface of the substrate excluding said insulating pattern.

Furthermore, according to an aspect of the present invention, there is provided a method of manufacturing an electronic component, comprising: a liquid attaching step to attach liquid, containing a specific ratio of metal particulates and vaporizing at a specific temperature, on a substrate having an insulating pattern formed of thermosetting resin; a heating step to heat said insulating pattern to which said liquid is attached, vaporize said liquid and at the same time dissolve the insulating pattern, and fix said metal particulates on the insulating pattern; and a metal particulate eliminating step to eliminate the metal particulates attached on the substrate excluding said insulating pattern.

Furthermore, according to an aspect of the present invention, there is provided an electronic component, comprising: a thermosetting resin layer formed on a substrate with a specific pattern; a metal conductor layer formed on said thermosetting resin layer; and a metal particulate layer interposed and buried in a boundary between, and extending over, said thermosetting resin layer and said metal conductor layer.

### BRIEF DESCRIPTION OF THE DRAWINGS

Whilst the present invention will be described with reference to the drawings, these drawings are provided only for the illustrative purpose and, in no respect, are intended to limit the present invention.

FIG. 1 is a schematic overview of a configuration of an electronic component manufacturing apparatus according to an embodiment of the present invention.

FIG. 2 is a schematic overview of a configuration of a metal particulate attaching apparatus according to the embodiment of the present invention.

FIG. 3 is a sectional view showing a state of metal particulates which are attached by using the metal particulate attaching apparatus according to the embodiment of the present invention.

FIGS. 4A AND 4B are another sectional views showing a state of metal particulates which are attached by using the metal particulate attaching apparatus according to the embodiment of the present invention.

FIG. 5 is a schematic overview of a configuration of another metal particulate attaching apparatus according to an embodiment of the present invention.

FIGS. 6A, 6B, 6C, 6D, and 6E are schematic sectional views showing an example of a formation step of a monolayer electronic circuit board according to an embodiment of the present invention.

FIGS. 7F, 7G, 7H, 7I, and 7J are schematic sectional views showing an example of the forming step of the multi-layer electronic circuit board according to the embodiment of the present invention.

### DESCRIPTION OF THE EMBODIMENTS

In the following, an embodiment of the present invention will be described with reference to the drawings.

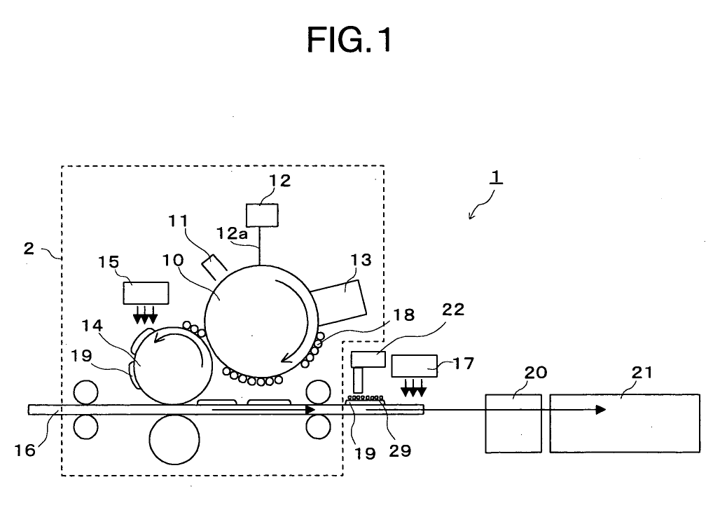

FIG. 1 shows an overview of a configuration of an electronic component manufacturing apparatus 1 according to an embodiment of the present invention.

The electronic component manufacturing apparatus 1 according to the embodiment of the present invention consists mainly of: a resin pattern forming apparatus 2 to form, on a substrate 16, a resin pattern serving as an insulating pattern; a metal particulate attaching apparatus 22 to attach metal particulates 29 on a resin layer 19 formed on the substrate 16; a heating apparatus 17 to heat the resin layer 19; a metal particulate eliminating apparatus 20 to eliminate metal particulates 29 attached on the substrate 16; and an electroless plating tank 21 to form a metal conductor layer 19, which has metal particulates 29 attached thereon.

Here, FIG. 1 shows, as an example of the resin pattern forming apparatus 2, a resin pattern forming apparatus using an electrophotograhic method to charge a surface of a photosensitive drum 10 by a corona charger 11, form a specified latent pattern by irradiating laser beam over the surface of the photosensitive drum 10 by a laser generating/scanning apparatus 12, make resin particles 18 electrostatically adsorbed by the latent pattern on the surface of the photosensitive drum 10, make a visible image (pattern) formed of resin particles 18 on the surface of the photosensitive drum 10 contact with, and pressed by, a surface of an intermediate transfer drum 14 heated by the heating apparatus 15, and transfer the pattern to the substrate using the viscosity of the resin.

It should be noted that the resin pattern forming apparatus 2 is not limited to an apparatus using the electrophotographic method described herein. For example, apparatuses by conventionally used methods, such as the inkjet method to form a resin pattern by spraying from a nozzle a resin in paste form, or the screen printing method to form a resin pattern by using a pattern-corresponding mask to print a resin in paste form, can be used.

In this embodiment, a dry or a wet toner transfer technique for a known electrophotographic transfer system can be applied to an imaging apparatus 13 in the resin pattern forming apparatus 2. When the imaging apparatus 13 is a dry one, it stores resin particles 18 having the size of 3 to 50 μm. Here, a preferable size of the resin particle is 8 to 15 μm. On the other hand, when the imaging apparatus is a wet one, the imaging apparatus 13 stores resin particles 18 having the size not exceeding 3 μm.

Further, as resin forming the resin particles 18, B-stage thermosetting resin, which is solid at a room temperature, can be used. The B stage is a state in which at least a part of the thermosetting resin is not cured, and provision of a specific heat dissolves the uncured part. Those usable as the B-stage thermosetting resin are epoxy resin, polyimide resin, phenolic resin, and the like, and a charge control agent may be added thereto, where it is necessary. Further, such particulates as silica included with a specific ratio may be dispersed within the resin particle 18, which in particular contributes to the controlling of characteristics such as stiffness or thermal expansion coefficient of the multi-layer electronic circuit board. As a result, the reliability of the board can be enhanced.

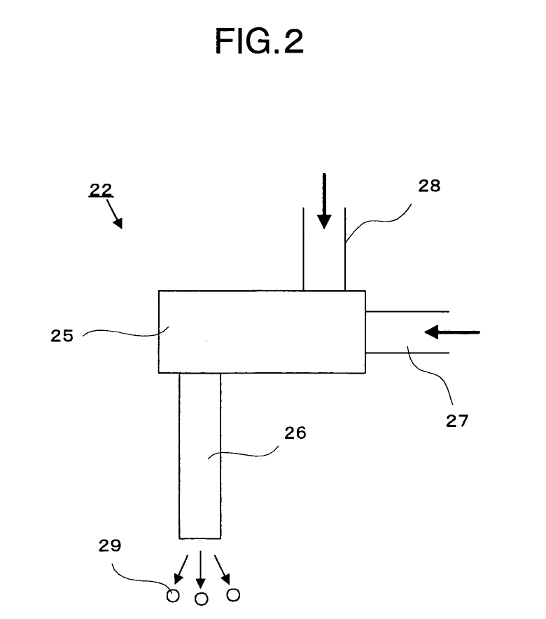

Subsequently, the metal particulate attaching apparatus 22 will be explained with reference to FIGS. 2 to 5.

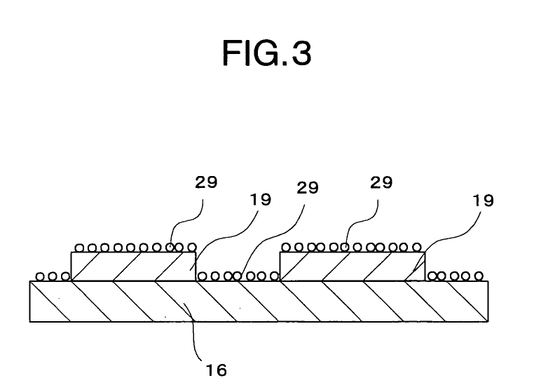

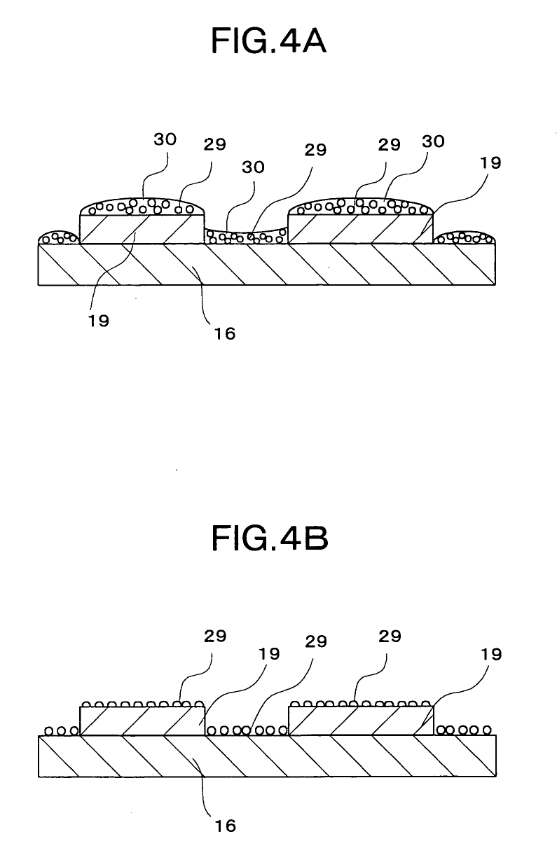

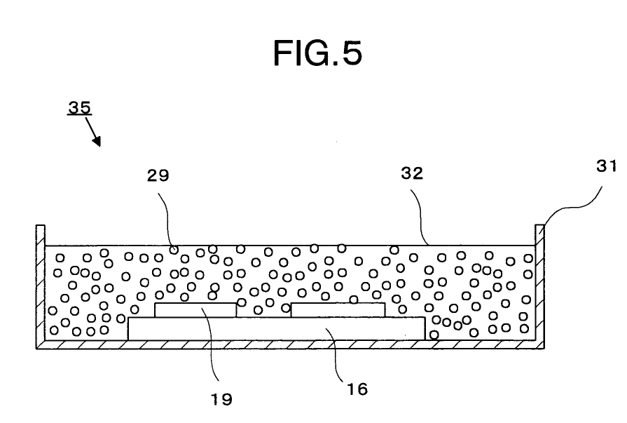

FIG. 2 shows a configuration of an embodiment of the metal particulate attaching apparatus 22. FIGS. 3 to 4 show sectional views of a state in which the metal particulates 29 are attached by using the metal particulates attaching apparatus 22. FIG. 5 shows a configuration of a metal particulate attaching apparatus 35, which is another example other than the metal particulate attaching apparatus 22.

The metal particulate attaching apparatus 22 shown in FIG. 2 is an apparatus to spray the metal particulates 29 over the resin layer transferred on the substrate 16, and consists mainly of a blending section 25 and a spray nozzle 26 connected to a lower surface of the blending section 25.

The blending section 25 are connected to a compressed air line 27 to supply a compressed air, and a metal particulate line 28 to supply the metal particulates 29 to the blending section 25. When the compressed air is supplied to the blending section 25, the metal particulates 29 disperse almost evenly in the blending section 25 during the period they are staying in the blending section 25. The metal particulates 29 are then led to the spray nozzle 26 which communicates with the blending section 25, and, with the compressed air, ejected from ejection holes of the spray nozzle 26 over the resin layer 19.

The metal particulates 29 ejected over the resin layer 19 are attached on the upper surface of the resin layer 19, as shown in FIG. 3. Here, the proportion of a surface coverage ratio indicating the area of the resin layer 19 covered by the metal particulates 29 to the area of the upper surface of the resin layer 19 is preferred to be 10 to 100%. A surface coverage ratio of less than 10% may result in insufficient precipitation of the plating. A more preferable surface cover age ratio is 50 to 80%. Incidentally, the metal particulates 29 ejected over the resin layer 19 can be attached not only on the upper surface of the resin layer 19, but it is also possible to attach the metal particulates 29 on a side surface of the resin layer 19.

Subsequently, the substrate 16 is led to and heated by the heating apparatus 17 and cure the resin layer 19, and the metal particulates 29 are fixed on the upper surface of the resin layer 19. Here, a part of the metal particulates 29 fixed on the upper surface of the resin layer 19 are not buried into the resin layer 19, but projects externally on the upper surface of the resin layer 19. These externally projecting metal particulates 29 become a plating nucleus for an electroless plating, allowing forming of a metal conductor layer having favorable conductive properties.

The volumes of the compressed air and the metal particulates 29 supplied to the blending section 25 can be regulated by, for example, providing regulating valves (not shown) or the like to a compressed air line 27 and a metal particulate line 28. It is noted that while a working fluid herein used for dispersing the metal particulates 29 is air, this is not a limitation, and for example, inert gas such as nitrogen can be used. Here, the temperature of the working fluid may be controlled so as to dissolve and keep the viscosity of the surface of the resin pattern.

As the metal particulate 29, a metal particulate formed at least one of the group of platinum (Pt), palladium (Pd), copper (Cu), gold (Au), nickel (Ni), and silver (Ag) is preferably used. Such metal particulates 29 become a nucleus of the electroless plating which will be described later, and play a catalytic role in the plating step. In the group, palladium (Pt) is in particular preferable for use. Further, the average particle size of the metal particulate 29 is preferable within 5 nm to 1000 nm, and more preferable within 5 nm to 500 nm. This is because smaller average particle size of the metal particulates 29 permit high dispersibility.

The above-described method of ejecting the metal particulates 29 over the resin layer 19 by the compressed air and attaching the metal particulates 29 on the upper surface of the resin layer 19 is suitable when the size of the metal particulates 29 to be used is relatively large within its average particle size of 5 nm to 1000 nm.

Specifically, when the average particle size of the metal particulates 29 to be used is small, a liquid in which the metal particulates are dispersed can be used, the solvent medium of which, for example, is formed of aromatic solvent such as toluene, xylene, mineral spirit, and isoparaffin, and a liquid of relatively low boiling point such as water and spirits. A state of the resin layer 19 in the case of using liquid is shown in FIG. 4A. For the liquid 30, is suitable a liquid which vaporizes at the temperature at which the resin to be used is cured (for example, 150° C. to 200° C.) or at a lower temperature thereof.

In the case of using the liquid 30 as a working fluid, in the liquid 30 the metal particulates may be dispersed in the solvent in advance, or a stirrer may be provided within the blending section 25, to stir the metal particulates 29 and the liquid 30 so that the metal particulates 29 are dispersed evenly in the liquid 30.

Here, the ratio of the metal particulates 29 included in the liquid 30 is preferably within 1 to 50% by weight. When the ratio of the metal particulates 29 included in the liquid 30 is less than 1% by weight, the function of the metal particulates 29 fixed on the resin layer as a plating nucleus may deteriorate. On the other hand, when the ratio of the metal particulates 29 included in the liquid 30 is larger than 50% by weight, it becomes difficult to spray the liquid 30 evenly from the spray nozzle 26. Additionally, a more preferable ratio of the metal particulates 29 included in the liquid 30 is within 1 to 20% by weight.

Subsequently, a pressurizer to pressurize the inside of the blending section 25 is provided, and the liquid 30 containing the metal particulates 29 is sprayed over the resin layer 19 from the spray nozzle 26. The metal particulates 29 sprayed over the resin layer 19 adhere on the upper surface of the resin layer 19 together with the liquid 30, as shown in FIG. 4A. Incidentally, the pressurizer may include an electromagnetic pump interposed between the spray nozzle 26 and the blending section 25. Further, for the spray nozzle 26, it is preferable to use an atomizing nozzle such as a pressure spraying valve or an air-spraying valve.

Instead of spraying liquid 30 including the metal particulates 29 from the spray nozzle 26, the liquid 30 may be coated over the resin layer 19 as liquid column. In such a case, the liquid 30 is flown out by its own weight, without a pressurizier. Here, the spray nozzle 26 to be used may be, for example, a barrel unit such as a pipe, but it is not a limitation, and anything allowing coating of the liquid 30 over the resin layer 19 as liquid column may be used.

Subsequently, the substrate 16 is led to, for example, the heating apparatus 17, and the liquid 30 vaporizes by heating. When the liquid 30 vaporizes, the metal particulates 29 adhere on the upper surface of the resin layer 19. Heated by the heating apparatus 17, the resin layer 19 dissolves, and is cured, so that the metal particulates 29 are fixed on the upper surface of the resin layer 19, as shown in FIG. 4B. Here, a part of the metal particulates 29 fixed on the upper surface of the resin layer 19 are not buried into the resin layer 19, but projecting externally on the upper surface of the resin layer 19. The externally projecting metal particulates 29 become a plating nucleus for the electroless plating, allowing forming of the metal conductor layer having favorable conductive properties.

Here, the curing of the resin layer 19 and the vaporizing of the liquid 30 are simultaneously carried out by the heating apparatus 17, but the liquid 30 can be vaporized before leading the substrate 16 to the heating apparatus 17, by separately providing a vaporizer to vaporize the liquid 30.

Further, other than spraying over the resin layer 19 the liquid 30 by including the metal particulates 29, a metal particulate attaching apparatus 35 shown in FIG. 5, can be used to attach the metal particulates 29 on the rein layer 19.

This metal particulate attaching apparatus 35 includes an accommodating container 31 to accommodate the substrate 16, and a liquid 32 containing the metal particulates 29 stored in the accommodating container 31.

The liquid 32 stored in the accommodating container 31 is formed of the same liquid as the liquid 30 used as the working fluid described above. For example, aromatic solvent such as toluene, xylene, mineral spirit, and isoparaffin, and a liquid of relatively low boiling point such as water and spirits can be used as the liquid 32. For the liquid 32, suitable is a liquid which vaporizes at the temperature at which the resin to be used is cured (for example, 150° C. to 200° C.) or at a lower temperature thereof.

A preferred ratio of the metal particulates 29 included in the liquid 32 is within the range of 1 to 5o% by weight. If the ratio of the metal particulates 29 included in the liquid 32 is less than 1%, the plating precipitation may become insufficient. On the other hand, if the ratio of the metal particulates 29 included in the liquid 32 is more than 50% by weight, the metal particulates 29 may not adhere on the resin layer 19 at the intended ratio of surface coverage. Further, a more preferable ratio of the metal particulates 29 included in the liquid 32 is 1 to 20% by weight.

The substrate 16, to which the resin layer 19 is transferred, is dipped for a certain period of time in the accommodating container 31 storing the liquid 32, and picked out. On the surface of the substrate 16 and the resin layer 19, the liquid 32 containing the metal particulates 29 adheres, as shown in FIG. 4A.

Subsequently, the substrate 16 is led to, for example, the heating apparatus 17, and heated such that the liquid 32 vaporizes. When the liquid 32 vaporizes, the metal particulates 29 adhere on the upper surface of the resin layer 19. Further, heated by the heating apparatus 17, the resin layer 19 dissolves, and is then cured, so that the metal particulates 29 adhere on the upper surface of the resin layer 19, as shown in FIG. 4B. Here, a part of the metal particulates 29 fixed on the upper surface of the metal layer 19 project over the upper surface of the resin 19, without being buried into the resin layer 19. These metal particulates 29 projecting externally become a plating nucleus for the electroless plating, allowing forming of the metal conductor layer having favorable conductive properties.

In the case hereof, the curing of the resin layer 19 and the vaporizing of the liquid 32 are simultaneously carried out by the heating apparatus 17, but it is also possible to separately provide a vaporizer to vaporize the liquid 32 so that the liquid 32 vaporizes before the substrate 16 is led to the heating apparatus 17.

Here, a tensile strength test is performed to evaluate the adhesiveness between the resin layer and the substrate, in which are compared the substrate having the resin layer 19 attaching the metal particulates 29 on its upper surface, and the substrate having the resin layer containing the metal particulates 29 dispersed almost evenly. The ratio of the metal particulates in the resin layer containing the metal particulates is 50% by weight.

The tensile strength measurement result is 50 MPa for the substrate having the resin layer which fixes the metal particulates 29 on the surface thereof, and 20 MPa for the substrate having the metal-particulate-including resin layer. This measurement results indicate that with the resin layer 19 having the metal particulates 29 fixed on the upper surface thereof, the strength of the resin layer, more specifically, the strength of the adhesive layer itself between the conductor layer and the substrate, becomes high, because it is only on the upper surface of the resin layer 19 that the metal particulates 29 are fixed. As a result, a wiring pattern with a high adhesiveness with the substrate and a sustained mechanical strength can be formed.

Next, an example of operations of an electronics component manufacturing apparatus 1 will be explained.

The substrate 16 to which the resin layer 19 is transferred by the resin pattern forming apparatus 2 is led to the metal particulate attaching apparatus 22. The metal particulates are attached on the upper surface of the resin layer 19 of the substrate 16 having led to the metal particulate attaching apparatus 22.

Subsequently, the substrate 16 having the resin layer 19 attaching the metal particulates 29 on the upper surface thereof is led to the heating apparatus 17, and the resin layer 19 at the B stage having transferred to the substrate 16 is cured by heating or light irradiating. Here, the metal particulates 29 adhering over the resin layer 19 is fixed over the resin layer 19 by the curing of the rein layer.

Subsequently, the substrate 16 is led to the metal particulate eliminating apparatus 20, where the metal particulates 29 adhering on the substrate 16 are eliminated, excluding the resin layer. In the metal particulate eliminating apparatus 20, the metal particulates 29 are eliminated by, for example, shot blast, air blast, ultrasonic cleaning, or the like.

The substrate 16, the metal particulates 29 adhering on which are eliminated excluding the resin layer 19, is led to an electroless plating tank 21 for copper, where copper is specifically precipitated, with the metal particulates 29 as the plating nucleus. As a result, a conductor pattern having a favorable conductivity can be formed. It is noted that while herein presented is a plating apparatus composed only of the electroless plating tank 21, this is not a limited way, and both the electroless plating and electrolytic plating can be carried out.

After the plating, it is preferable to completely cure the resin layer 19 by reheating or irradiating with the heating apparatus 17, such that the substrate 16 and the resin layer 19 further adhere to each other and any removal or the like can be prevented. The thickness of the resin layer 19 when it is completely cured is 0.5 μm to 15 μm.

It is noted that, in the case where the metal particulates 29 are sprayed over the resin layer 19 using air or the like in the metal particulates attaching apparatus 22, the resin layer 19 having high viscosity is preferred, such as the one formed on the substrate 16 herein described. For example, before led to the metal particulate attaching apparatus 22, the resin layer 19 formed on the substrate 16 is preferably heated in advance, so that the resin layer 19 becomes viscid. In that case, for example, a heating apparatus is provided before the entry of the resin layer 19 to the metal particulate attaching apparatus 22, which allows the metal particulates to adhere on the rein layer 19 appropriately. Further, when an inkjet method or a screen printing method is employed to the resin pattern forming apparatus 2, the metal particulates can be attached using the adhesiveness of the resin layer 19 over the substrate 16.

In addition, the electroless plating is carried out over the resin layer 19 after fixing the conductive metal particulates 29 which are the plating nucleus for the electroless plating, in the manner that a part of which project over the upper surface of the resin layer 19, so that a metal conductor layer having a favorable conductivity can be formed.

Further, a flexible multi-layer electronic circuit board can be manufactured in the manner that a board or a sheet formed of PTFE resin is used as a substrate to form an insulating pattern and a conductor pattern alternatively, and the multi-layer circuit wiring part so formed is peeled off from the substrate.

Furthermore, an electronic circuit board manufactured as a substrate by a conventional method (for example, a subtractive board) may be used, on which a conductor pattern is formed by the above-described forming method. When manufacturing a substrate, to which heat-resistance is not required, thermoplastic resin such as an acrylic resin can be used instead of the thermosetting resin which is processed up to the B stage.

(An example of a configuration and formation step of a monolayer electronic circuit board or a multi-layer electronic circuit board)

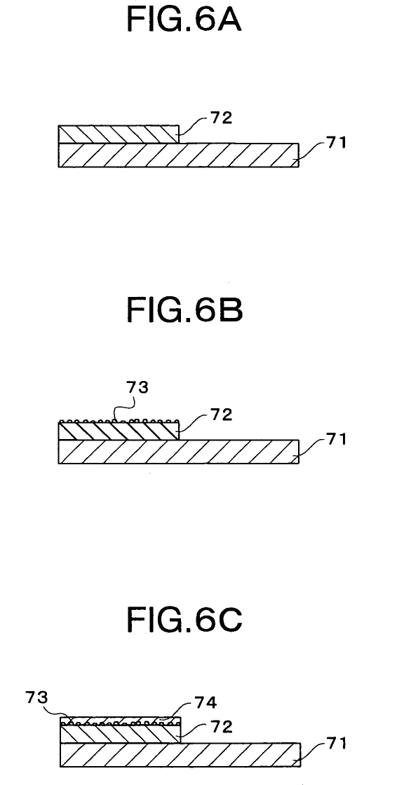

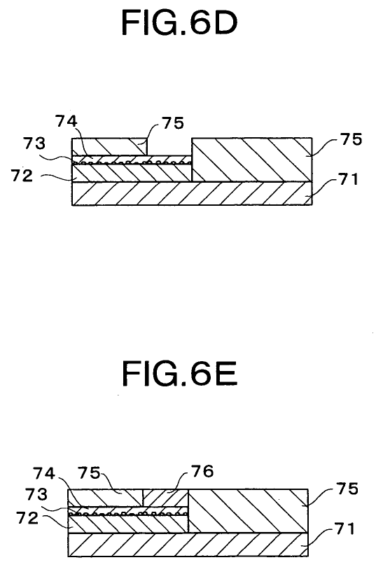

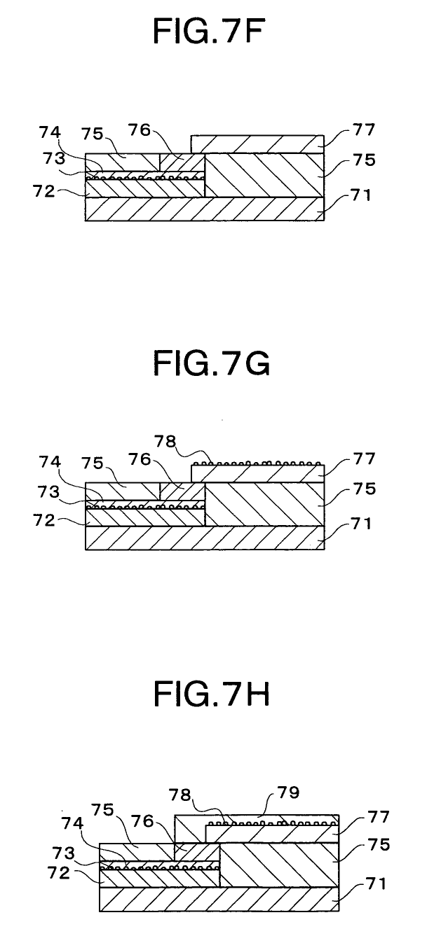

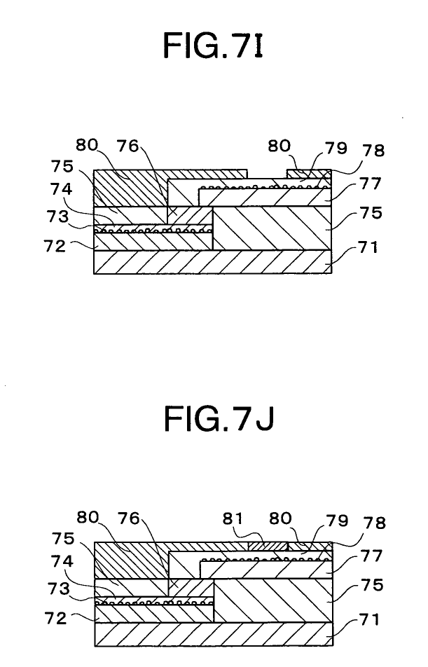

First, an example of a formation step of a monolayer electronic circuit board will be explained with reference to FIGS. 6A to 6E. Subsequently, an example of a formation step of a multi-layer electronic circuit board by forming another electronic circuit on the monolayer electronic circuit board will be explained with reference to FIGS. 7f to 7J.

FIGS. 6A, 6B, 6C, 6D, and 6E are sectional views showing the formation steps of the monolayer electronic board. FIGS. 7F, 7G, 7H, 7I and 7J are sectional views showing the formation steps of the multi-layer electronic board, following the formation steps of the monolayer electronic circuit board shown in FIGS. 6A to 6E. It is noted that the following examples of the formation steps of the monolayer electronic circuit board and the multi-layer electronic circuit board are carried out based on the above-described operational example of the electronic circuit manufacturing apparatus 1, and explanations on the overlapping operations will be omitted.

First, the formation step of the monolayer electronic circuit board shown in FIGS. 6A to 6E will be explained.

Over a substrate 71, a resin layer 72 is formed with a predetermined conductor pattern (FIG. 6A), and on the upper surface of the resin layer 72, metal particulates are attached, so as to form a metal particulate layer 72 (FIG. 6B).

Subsequently, the upper surface of the resin layer 72 having the metal particulate layer 73 fixed thereover is electrolessly plated, so as to form a conductive metal layer 74 formed of a layer of plating by copper or the like (FIG. 6C).

A resin layer 75 is then formed on the metal particulate layer excluding a part for forming a via layer 76 on the conductive metal layer 74, and on the substrate 71 (FIG. 6D).

A via layer 76 is then formed by electrolessly plating the recess for forming the via layer 76 on the conductive metal layer 74 (FIG. 6E). With the above process, a monolayer electronic circuit board is formed.

Next, a step to form a multi-layer electronic board by forming another electronic circuit on the monolayer electronic circuit board will be explained, with reference to FIGS. 7F, 7G, 7H, 7I, and 7J.

In order to form a second layer on the monolayer electronic circuit board formed by the monolayer electronic circuit board forming step, a resin layer 77 is formed with a predetermined pattern, on an area which extends over a part of the via layer 76, and on the resin layer 75 (FIG. 7F).

Metal particulates are then fixed on the upper surface of the resin layer 77, so as to form a metal particulate layer 78 (FIG. 7G).

Electroless plating is then carried out over the surface of the via layer 76 and on the upper surface of the resin layer 77 having the metal particulate layer 78 fixed thereon, so as to form a conductive metal layer 79 formed of a layer of plating by copper or the like (FIG. 7H).

A resin layer 80 is then formed on the conductive metal layer 79 excluding a part for forming a via layer 81, and on the resin layer 75 (FIG. 7I).

A via layer 81 is then formed by electrolessly plating the recess for forming the via layer 81 on the conductive metal layer 79 (FIG. 7J).

Thereafter, the steps shown in FIG. 7F and thereon are repeated such that a multi-layer electronic circuit board composed of a plurality of layers can be formed.

Further, on the monolayer electronic circuit board and the multi-layer electronic circuit board, a metal particulate layer is formed, in which at least a part of the conductive metal particulates are projecting over the surface of the resin layer forming a conductor pattern, so that plating can be carried out with the projecting metal particulates as the plating nucleus. This permits the metal particulates to serve as catalyst in the progress of the plating, so that an electronic circuit board can be obtained in which a conductive metal layer of a favorable state is appropriately formed on the resin layer forming the conductor pattern. After the conductor pattern is plated, the metal particulates lie in the boundary portion between the resin layer and the conductive metal layer extending over respective layers.

According to the one embodiment of the present invention described above, a part of the metal particulates projecting and serving as the plating nucleus can be evenly fixed on the surface of the resin layer. This allows an optimal plating, so that a conductive metal layer of a favorable state can be formed.

Further, according the one embodiment of the present invention, the resin layer of the conductor pattern forms an insulating resin layer without having metal particulates included in, or attached on the surface of, each of resin particles, and thereafter has the metal particulates fixed thereon, so that a toner (resin particles 18) of a desired size, weight, quantity of electric charges, can be easily fabricated.

Furthermore, the resin layer for forming the conductor pattern has metal particulates fixed only on the surface thereof, so that a wiring pattern having high cohesiveness between the conductor layer and the substrate and a sustained mechanical strength can be formed.

It is to be understood that the present invention is not limited to the specific aspects described herein with reference to the drawings, and includes all variations thereto insofar as they are included in the range claimed in the following.

1. An electronic component manufacturing apparatus, comprising:
a metal particulate spraying mechanism to spray metal particulates over a substrate having an insulating pattern formed of thermosetting resin and attach the metal particulates on said insulating pattern;
a heating mechanism to heat and dissolve said insulating pattern and fix said metal particulates on said insulating pattern; and
a metal particulate eliminating mechanism to eliminate the metal particulates attached on the surface of the substrate excluding said insulating pattern.

2. An electronic component manufacturing apparatus, comprising:
a liquid attaching mechanism to attach liquid, containing a specific ratio of metal particulates and vaporizing at a specific temperature, on a substrate having an insulating pattern formed of thermosetting resin;
a heating mechanism to heat said insulating pattern to which said liquid is attached, vaporize said liquid and at the same time dissolve said insulating pattern, and fix said metal particulates on said insulating pattern; and
a metal particulate eliminating mechanism to eliminate the metal particulates attached on the substrate excluding said insulating pattern.

3. A method of manufacturing an electronic component, comprising:
a metal particulate spraying step to spray metal particulates over a substrate having an insulating pattern formed of thermosetting resin and attach the metal particulates on said insulating pattern;
a heating step to heat and dissolve said insulating pattern and fix said metal particulates on said insulating pattern; and
a metal particulate eliminating step to eliminate the metal particulates attached on the surface of the substrate excluding said insulating pattern.

4. A method of manufacturing an electronic component, comprising:
a dissolving step to heat and dissolve an insulating pattern formed of thermosetting resin and formed on a substrate;
a metal particulate spraying step to spray metal particulates over said substrate having the insulating pattern which is dissolved, and attach the metal particulates on the dissolved insulating pattern;
a curing step to heat and cure said insulating pattern, which has said metal particulates attached thereon, and fix said metal particulates on said insulating pattern; and
a metal particulate eliminating step to eliminate the metal particulates attached on the surface of the substrate excluding said insulating pattern.

5. A method of manufacturing an electronic component, comprising:
a liquid attaching step to attach liquid, containing a specific ratio of metal particulates and vaporizing at a specific temperature, on a substrate having an insulating pattern formed of thermosetting resin;
a heating step to heat said insulating pattern to which said liquid is attached vaporize said liquid and at the same time dissolve the insulating pattern, and fix said metal particulates on the insulating pattern; and
a metal particulate eliminating step to eliminate the metal particulates attached on the substrate excluding said insulating pattern.

6. An electronic component, comprising:
a thermosetting resin layer formed on a substrate with a specific pattern;
a metal conductor layer formed on said thermosetting resin layer; and
a metal particulate layer interposed and buried in a boundary between, and extending over, said thermosetting resin layer and said metal conductor layer.
